(19) United States
(12) Patent Application Publication
(10) Pub. No.: US 2006/0234395 A1
(43) Pub. Date: Oct. 19, 2006

(54) Method for manufacturing perovskite type oxide layer, method for manufacturing ferroelectric memory and method for manufacturing surface acoustic wave element

(75) Inventor: Takeshi Kijima, Matsumoto (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/403,994

(22) Filed: Apr. 13, 2006

(30) Foreign Application Priority Data
Apr. 14, 2005 (JP) 2005-117217

(51) Int. Cl. H01L 21/00

(52) U.S. Cl. 438/3

(57) ABSTRACT

A method for manufacturing a perovskite type oxide layer includes the steps of: forming, above a substrate, a first oxide layer composed of perovskite type oxide; forming, above the first oxide layer, a second oxide layer composed of at least one of a perovskite type oxide layer crystallized at a temperature lower than a crystallization temperature of the first oxide layer and a pyrochlore layer having elements identical with elements of the perovskite type oxide; forming an electrode layer above the second oxide layer; and conducting a heat treatment.

The entire disclosure of Japanese Patent Application No. 2005-117217, filed Apr. 14, 2005 is expressly incorporated by reference herein.

### BACKGROUND

1. Technical Field

The present invention relates to a method for manufacturing a perovskite type oxide layer, a method for manufacturing a ferroelectric memory and a method for manufacturing a surface acoustic wave element.

2. Related Art

Perovskite type oxide is known as one of oxides which have the characteristics of ferroelectric or piezoelectric material. An element having a perovskite type oxide layer may be formed for example in the following manner.

First, a precursor layer is formed on a substrate by coating a precursor composition (sol-gel solution) of perovskite type oxide. Then, the precursor layer is subject to drying and cleaning processing to thereby remove organic compositions in the precursor layer, whereby an amorphous oxide layer is formed. Then, the oxidation layer is crystallized by heat treatment, thereby forming a perovskite type oxide layer having a desired orientation. Then, an electrode layer is formed on the perovskite type oxide layer by, for example, a sputter method, and the electrode layer is then patterned according to the necessity. Then, recovering heat treatment (post anneal) is conducted to recover the crystallinity from defects at an interface between the electrode layer and the perovskite type oxide layer.

According to the method described above, in the post annealing, the post anneal temperature is normally set higher than the crystallization temperature of the oxide layer in order to cause re-crystallization of the oxide layer and the electrode layer. This method entails the following problems. The high temperature post annealing gives excessive thermal energy to the perovskite type oxide that has been crystallized to have a desired orientation, such that lattice vibration of the perovskite type crystal structure becomes excessive. As a result, defects may be generated in the perovskite type crystal structure. For example, in the case of PZT (e.g., Pb (Zr, Ti)O₃), Pb vacancy at the interface between the oxide layer and the electrode layer and oxygen vacancy due to Frenkel defects of Ti in the oxide layer would likely occur. Also, due to the post annealing at high temperatures, a deteriorated layer (i.e., heterogeneous phase) would likely be formed at the interface between the oxide layer and the electrode layer by element diffusion from both sides. Because such oxygen vacancy and deteriorated layers are formed, the characteristics and reliability of the device become insufficient.

### SUMMARY

In accordance with an advantage of some aspects of the present invention, there are provided a method for manufacturing a perovskite type oxide layer, a method for manufacturing a ferroelectric memory and a method for manufacturing a surface acoustic wave element, in which a perovskite type oxide layer and an electrode layer have an excellent interface.

In accordance with an embodiment of the invention, a method for manufacturing a perovskite type oxide layer includes the steps of: forming, above a substrate, a first oxide layer composed of perovskite type oxide; forming, above the first oxide layer, a second oxide layer composed of at least one of a perovskite type oxide layer crystallized at a temperature lower than a crystallization temperature of the first oxide layer and a pyrochlore layer having elements identical with those of the perovskite type oxide; forming an electrode layer above the second oxide layer; and conducting a heat treatment.

According to the manufacturing method described above, an excellent interface can be formed between the perovskite type oxide layer and the electrode layer, as described below.

It is noted that, in the invention, forming another specific member (hereafter referred to as “B”) above a specific member (hereafter referred to as “A”) includes a case of forming “B” directly on “A,” and a case of forming “B” over “A” through another member on “A.” Also, in the invention, “B” formed above “A” includes “B” formed directly on “A,” and “B” formed above “A” through another member on “A.”

In the manufacturing method in accordance with an aspect of the embodiment of the invention, the heat treatment may be conducted at temperatures below the crystallization temperature of the first oxide layer.

In the manufacturing method in accordance with an aspect of the embodiment of the invention, the second oxide layer may include the pyrochlore layer, and the pyrochlore layer may be changed to a perovskite type oxide layer by the step of the heat treatment.

In the manufacturing method in accordance with an aspect of the embodiment of the invention, in the step of forming the first oxide layer, the first oxide layer may have a specific crystal orientation.

In the manufacturing method in accordance with an aspect of the embodiment of the invention, the first oxide layer may be formed by a liquid phase method, and the second oxide layer may be formed by a vapor phase method.

In accordance with another embodiment of the invention, a method for manufacturing a ferroelectric memory includes the steps of: forming, above a substrate, a lower electrode; forming, above the lower electrode, a first oxide layer composed of perovskite type oxide; forming, above the first oxide layer, a second oxide layer composed of at least one of a perovskite type oxide layer crystallized at a temperature lower than a crystallization temperature of the first oxide layer and a pyrochlore layer having elements identical with those of the perovskite type oxide; forming an upper electrode above the second oxide layer; and conducting a heat treatment.

In accordance with still another embodiment of the invention, a method for manufacturing a surface acoustic wave element includes the steps of: forming, above a substrate, a first oxide layer composed of perovskite type oxide; forming, above the first oxide layer, a second oxide layer composed of at least one of a perovskite type oxide layer crystallized at a temperature lower than a crystallization temperature of the first oxide layer and a pyrochlore layer having elements identical with those of the perovskite type oxide; forming an electrode above the second oxide layer; and conducting a heat treatment.

The perovskite type oxide layer in accordance with the embodiments of the invention has an excellent interface with the electrode layer, and has excellent characteristics as a layer of ferroelectric material or piezoelectric material. Accordingly, the perovskite type oxide layer of the present embodiment can be applied to devices having ferroelectric layers, such as, for example, ferroelectric memory devices. Also, the perovskite type oxide layer of the present embodiment can be applied to devices having piezoelectric layers, such as, for example, surface acoustic wave elements (i.e., SAW devices: surface acoustic wave devices).

In accordance with the embodiments of the invention, the perovskite type oxide may be expressed by a general formula of ABO₃, and may be simple perovskite type oxide, compound perovskite type oxide, or layered perovskite type oxide.

### BRIEF DESCRIPTION OF THE DRAWINGS

FIG. 1 is a cross-sectional view schematically showing a step of a manufacturing method in accordance with a first embodiment of the invention.

FIG. 2 is a cross-sectional view schematically showing a step of the manufacturing method in accordance with the first embodiment of the invention.

FIG. 3 is a cross-sectional view schematically showing a step of the manufacturing method in accordance with the first embodiment of the invention.

FIG. 4 is a cross-sectional view schematically showing a step of a manufacturing method in accordance with a second embodiment of the invention.

FIG. 5 is a cross-sectional view schematically showing a step of a manufacturing method in accordance with a third embodiment of the invention.

FIG. 6 shows X-ray diffraction diagrams of a first exemplary embodiment.

FIG. 7 shows X-ray diffraction diagrams of the first exemplary embodiment.

FIG. 8 shows X-ray diffraction diagrams of a second exemplary embodiment.

FIG. 9 shows X-ray diffraction diagrams of the second exemplary embodiment.

### DESCRIPTION OF EXEMPLARY EMBODIMENTS

Preferred embodiments of the present invention are described below with reference to the accompanying drawings.

### 1. First Embodiment

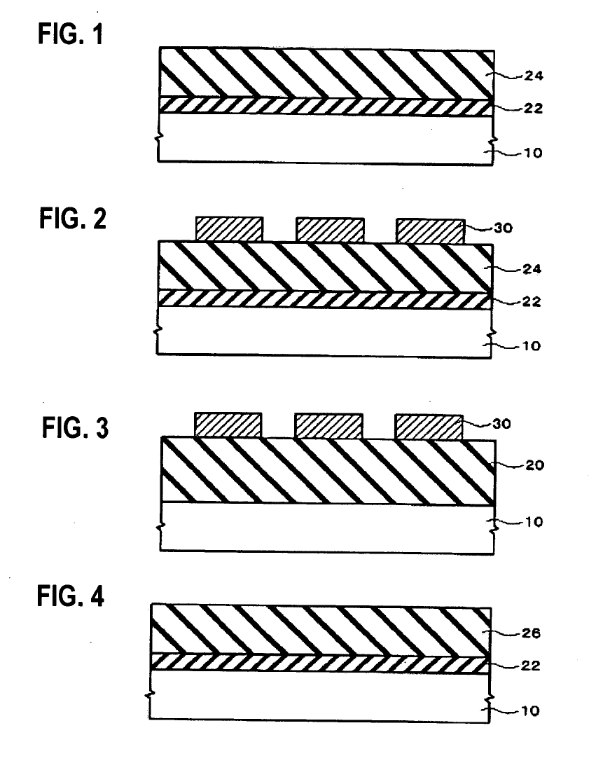

FIGS. 1 through 3 are cross-sectional views schematically showing steps of a manufacturing method in accordance with an embodiment of the invention.

(1) First, as shown in FIG. 1, a first oxide layer 22 is formed on a substrate 10. The first oxide layer 22 is formed with a crystal orientation of a perovskite type oxide layer that is to be finally obtained.

For example, the first oxide layer may be formed by epitaxial growth with respect to the substrate 10. In this case, the first oxide layer 22 grows with the same orientation as that of the substrate 10. As the substrate 10, a single crystal substrate, or a base material (not shown) with a so-called buffer layer having a crystal controllability formed thereon.

Any one of substrates in a variety of types can be used as the substrate 10 depending on the type and usage of the perovskite type oxide layer. For example, when the perovskite type oxide layer is used as a capacitor of a device such as a ferroelectric memory, a substrate with an electrode layer (e.g., a lower electrode) can be used as the substrate 10. When the perovskite type oxide layer is used as a surface acoustic wave element, a sapphire substrate or the like can be used as the substrate 10.

A known film forming method may be used as the method for forming the first oxide layer 22 without any particular limitation. As the film forming method, a liquid phase method such as a sol-gel method, or a vapor phase method such as a CVD method, a sputter method, a laser ablation method or the like can be used. Preferably, a liquid phase method such as a sol-gel method may be used to form the first oxide layer 22.

When a sol-gel method is used, a sol-gel raw material for forming perovskite type oxide is coated on the substrate 10, a heat treatment for drying and cleaning is then applied to the coated film, and a heat treatment is further conducted for crystallization of the coated layer. The temperature of the heat treatment for crystallization may differ depending on the kind of the perovskite type oxide and its crystal orientation, but may be 650° C. to 700° C., for example, in the case of PZT.

(2) Then, as shown in FIG. 1, a second oxide layer composed of a pyrochlore layer (hereafter also referred to as a “pyrochlore layer”) 24 is formed on the first oxide layer 22. The pyrochlore layer is composed of pyrochlore crystal having elements that are the same as those of the perovskite type oxide composing the first oxide layer 22.

The second oxide layer 24 is formed at a temperature lower than the temperature at which the first oxide layer 22 composed of perovskite type oxide layer is formed. Also, the second oxide layer 24 is formed at a temperature higher than the temperature at which organic compositions within the film are decomposed. In other words, the forming temperature of the second oxide layer 24, although it differs depending on the kind of the pyrochlore type oxide, may preferably be a temperature lower than the crystallization temperature of at least the first oxide layer 22, and at which crystallization of the second oxide layer 24 takes place and organic compositions in the layer are sufficiently decomposed. Normally, the crystallization temperature of a pyrochlore layer having the same elements as those of the first oxide layer 22 may be within such a temperature range. For example, when the first oxide layer 22 is composed of PZT, the second oxide layer (e.g., pyrochlore; Pb₂ (ZrTi)₂O₆) 24 can be formed in a temperature range between 400° C. and 500° C.

The second oxide (pyrochlore) layer 24 has an oxygen octahedral structure in its crystal structure, and abundant oxygen for changing to perovskite type oxide.

A known film forming method can be used as the method for forming the second oxide layer 24 without any particular limitation. As the film forming method, a liquid phase method such as a sol-gel method, or a vapor phase method such as a CVD method, a sputter method, a laser ablation method or the like.

(3) Then, as shown in FIG. 2, an electrode layer 30 having a desired pattern is formed on the second oxide layer 24.

The electrode layer 30 can be formed through forming a conductive layer by a known film forming method, and then forming the layer by using known lithography technique and etching method. A sputter method, a CVD method, a plating method or the like can be used as the method for forming the conductive layer without any particular limitation. The material of the conductive layer may be appropriately selected according to devices to which the perovskite type oxide layer of the present embodiment is applied without any particular limitation. For example, a metal, such as, for example, a platinum group metal, aluminum or the like, or a conductive oxide material, such as, for example, a platinum group metal oxide such as ruthenium oxide, iridium oxide or the like can be used.

(4) Next, heat treatment (hereafter referred to as “crystallization heat treatment”) is conducted to crystallize the second oxide layer 24, thereby forming a perovskite type oxide layer 20, as shown in FIG. 3. In other words, by the crystallization heat treatment, the second oxide layer 24 becomes a perovskite type oxide having a desired crystal orientation.

The crystallization heat treatment is conducted at a temperature at which the second oxide layer 24 sufficiently undergoes epitaxial growth on the first oxide layer 22, and preferably at a temperature lower than the crystallization temperature of the first oxide layer 22. The crystallization heat treatment in this step may be conducted at a temperature exceeding the crystallization temperature of the first oxide layer 22, but in this case, the temperature may be higher by up to a maximum of about 50° C.

If the temperature of the crystallization heat treatment is too low, the epitaxial growth of the second oxide layer 24 becomes insufficient, and a desired crystal orientation cannot be obtained. On the other hand, if the temperature of the crystallization heat treatment is too high, an undesired deteriorated layer may be generated by diffusion of materials of the perovskite type oxide layer 20 and the electrode layer 30 between the two layers, and lattice vibration of the perovskite type oxide may become excessive such that oxygen vacancies would likely be generated in the perovskite type oxide.

For example, when the perovskite type oxide is PZT, the crystallization heat treatment may be conducted between 600° C. and 700° C. In this case, if the temperature of the crystallization heat treatment exceeds about 700° C., a deteriorated layer (for example, a layer containing lead and elements of the electrode layer) may be formed between the PZT layer and the electrode layer, and Pb vacancy caused by evaporation of lead from the surface of the PZT layer and oxygen vacancy due to Frenkel defects of titanium in the PZT layer would likely occur.

In this step, pyrochlore type oxide in the second oxide layer 24 changes to perovskite type oxide. At this time, the perovskite type oxide becomes, by epitaxial growth, to have a structure having the same crystal orientation as that of the first oxide layer 22. As a result, as shown in FIG. 3, a perovskite type oxide layer 20 in a single layer and having a desired crystal orientation which is originated from the first oxide layer 22 and the second oxide layer 24 is formed. In this manner, the first oxide layer 22 functions as a buffer layer (i.e., a seed layer) having an orientation controlling function when the second oxide layer 24 changes to perovskite type oxide, such that the perovskite type oxide layer 20 can be formed at a relatively low temperature, and evaporation of lead can also be suppressed.

Also, in this step, the temperature of the crystallization heat treatment is lower than that of the conventional post annealing, its thermal energy is almost entirely consumed for changing the pyrochlore type oxide to the perovskite type oxide, and excessive thermal energy is not applied to the perovskite type oxide, such that the aforementioned problems caused by post annealing would be difficult to occur. Therefore, in accordance with the present embodiment, the perovskite type oxide layer 20 with an excellent crystal structure can be formed, and an excellent interface can be formed between the perovskite type oxide layer 20 and the electrode layer 30. As a result, high temperature heat treatment for defect recovery like the conventional post annealing is not additionally required.

In the embodiment described above, the pyrochlore layer composing the second oxide layer 24 is formed in a single layer. However, the present embodiment is not limited to such a structure, and the second oxide layer 24 may be composed of a plurality of pyrochlore layers. For example, a plurality of pyrochlore layers formed respectively at different forming temperatures can be laminated. In the present embodiment, in this case, the perovskite type oxide layer 20 having the same crystal orientation as that of the first oxide layer 22 can finally be obtained by the crystallization heat treatment.

Also, in the embodiment described above, the first oxide layer 22 is formed in a single layer, but the first oxide layer 22 may be composed of a plurality of layers. This can be similarly applied to other embodiments to be described below.

The present embodiment mainly has the following characteristics.

In accordance with the present embodiment, a pyrochlore layer composed of pyrochlore type oxide is used as the second oxide layer 24, such that the perovskite type oxide layer 20 with few oxygen vacancies can be formed. In other words, the pyrochlore layer has an octahedral structure, and the oxygen octahedral structure is effectively used when the pyrochlore type oxide changes to perovskite type oxide.

In accordance with the present embodiment, because a pyrochlore layer is used as the second oxide layer 24, organic compositions are sufficiently decomposed and removed when the oxide layer 24 is formed, and therefore carbon residue is not generated.

In accordance with the present embodiment, the perovskite type oxide layer 20 has an excellent crystal structure, and an excellent interface can be formed between the perovskite type oxide layer 20 and the electrode layer 30. For this reason, ferroelectric capacitors and piezoelectric elements to which the perovskite type oxide layer 20 of the present embodiment is applied can be expected to have excellent characteristics and reliability.

In accordance with the present embodiment, even when the second oxide layer 24 is formed in multiple layers, the perovskite type oxide layer 20 in a single layer having a desired crystal orientation can be obtained by the crystallization heat treatment.

Furthermore, in accordance with the present embodiment, as it becomes clear from exemplary embodiments to be described below, by controlling the temperature to form the second oxide layer 24 and its layer structure, the crystal grain size of the perovskite type oxide layer 20 to be finally obtained can be optionally set. Since the crystal grain size influences the ferroelectric characteristic and piezoelectric characteristic, the ability to control the crystal grain size is extremely useful. For example, in the case of piezoelectric, its piezoelectric property can be controlled by changing the number of grain boundaries.

### 2. Second Embodiment

FIG. 4 is a cross-sectional view schematically showing a step of a manufacturing method in accordance with a second embodiment of the invention. It is noted that members shown in FIG. 4 that are substantially the same as those of the first embodiment are appended with the same reference numbers, and their detailed description is omitted. The present embodiment differs from the first embodiment in that perovskite type oxide is used to compose a second oxide layer.

(1) First, as shown in FIG. 4, a first oxide layer 22 is formed on a substrate 10. The first oxide layer 22 is formed to have a crystal orientation of a perovskite type oxide (also hereafter referred to as “first perovskite type oxide”) layer that is desired to be finally obtained. The substrate 10 is similar to the substrate in the first embodiment.

(2) Next, as shown in FIG. 4, a second oxide layer 26 composed of second perovskite type oxide is formed on the first oxide layer 22.

The second perovskite type oxide composing the second oxide layer 26 has the same compositions as those of the first perovskite type oxide composing the first oxide layer 22, but a different structure from that of the first perovskite type oxide, for example, different crystal orientation and different crystal grain size.

The second oxide layer 26 may preferably be crystallized at a temperature lower than the crystallization temperature of at least the first oxide layer 22, and at which organic compositions are sufficiently decomposed, although such temperature may differ depending on the kind of the second perovskite type oxide composing the second oxide layer 26. The crystallization temperature of the second perovskite type oxide composing the second oxide layer 26 is normally within such a temperature range. For example, when the first oxide layer 22 is composed of PZT, the second oxide layer (PZT) 26 can be formed at a temperature ranging from 500° C. to less than 650° C. Also, when the second oxide layer 26 is crystallized, organic compositions within the film are decomposed. Therefore, organic compositions (carbon residue) do not exist in the second oxide layer 26.

A known film forming method may be used as the method for forming the second oxide layer 26 without any particular limitation. As the film forming method, a liquid phase method such as a sol-gel method, or a vapor phase method such as a CVD method, a sputter method, a laser ablation method or the like can be used.

(3) Then, an electrode layer 30 having a desired pattern is formed on the second oxide layer 26. This step can be conducted in a manner similar to the first embodiment.

(4) Then, heat treatment (hereafter referred to as “crystallization heat treatment”) is conducted to crystallize the second oxide layer 26, thereby forming a perovskite type oxide layer 20, as shown in FIG. 3. In other words, by the crystallization heat treatment, the second perovskite type oxide composing the second oxide layer 26 becomes to be first perovskite type oxide having a desired crystal orientation.

The crystallization heat treatment is conducted at a temperature at which the second oxide layer 26 sufficiently undergoes epitaxial growth on the first oxide layer 22, and preferably at a temperature lower than the crystallization temperature of the first oxide layer 22. The crystallization heat treatment in this step may be conducted at a temperature exceeding the crystallization temperature of the first oxide layer 22, but in this case, the temperature may be higher by up to a maximum of about 50° C.

If the temperature of the crystallization heat treatment is too low, the epitaxial growth of the second oxide layer 26 becomes insufficient, and a desired crystal orientation cannot be obtained. On the other hand, if the temperature of the crystallization heat treatment is too high, an undesired deteriorated layer may be generated by diffusion of materials of the perovskite type oxide layer 20 and the electrode layer 30 between the two layers, and lattice vibration of the perovskite type oxide may become excessive such that oxygen vacancies would likely be generated in the perovskite type oxide.

For example, when the perovskite type oxide is PZT, the crystallization heat treatment may be conducted between 600° C. and 700° C. In this case, if the temperature of the crystallization heat treatment exceeds 700° C., a deteriorated layer (for example, a layer containing lead and elements of the electrode layer) may be formed between the PZT layer and the electrode layer, and Pb vacancy caused by evaporation of lead from the surface of the PZT layer and oxygen vacancy due to Frenkel defects of titanium in the PZT layer would likely occur.

In this step, the second pyrochlore type oxide composing the second oxide layer 26 changes to the first perovskite type oxide. At this time, the second perovskite type oxide becomes, by epitaxial growth, to have a structure having the same crystal orientation as that of the first perovskite type oxide composing the first oxide layer 22. As a result, as shown in FIG. 3, a perovskite type oxide layer 20 in a single layer which is originated from the first oxide layer 22 and the second oxide layer 26 is formed. In this manner, the first oxide layer 22 functions as a buffer layer (i.e., a seed layer) having an orientation controlling function when the second oxide layer 26 changes to a portion of the perovskite type oxide layer 20, such that the perovskite type oxide layer 20 can be formed at a relatively low temperature, and evaporation of lead can also be suppressed.

Also, in this step, the temperature of the crystallization heat treatment is lower than that of the conventional post annealing, its thermal energy is almost entirely consumed for changing the second pyrochlore oxide to the first perovskite type oxide, and excessive thermal energy is not applied to the perovskite type oxide to be finally obtained, such that the aforementioned problems caused by high temperature heat treatment such as post annealing would be difficult to occur. Therefore, the perovskite type oxide layer 20 with an excellent crystal structure can be formed, and an excellent interface can be formed between the perovskite type oxide layer 20 and the electrode layer 30. As a result, high temperature heat treatment like the conventional post annealing is not additionally required.

In the embodiment described above, the second pyrochlore layer composing the second oxide layer 26 is formed in a single layer. However, the present embodiment is not limited to such a structure, and the second oxide layer 26 may be composed of a plurality of second perovskite type oxide layers. For example, a plurality of second perovskite type oxide layers crystallized respectively at different crystallization temperatures can be laminated. In the present embodiment, in this case, the perovskite type oxide layer 20 having the same crystal orientation as that of the first oxide layer 22 can be finally obtained by the crystallization heat treatment.

The present embodiment has the following characteristics.

In accordance with the present embodiment, a second perovskite type oxide layer is used as the second oxide layer 26, such that the perovskite type oxide layer 20 with few oxygen vacancies can be formed with relatively low energy.

In accordance with the present embodiment, because a second perovskite type oxide layer is used as the second oxide layer 26, organic compositions are sufficiently decomposed and removed when the oxide layer 26 is formed, and therefore carbon residue is not generated.

In accordance with the present embodiment, the perovskite type oxide layer 20 has an excellent crystal structure like the first embodiment, and an excellent interface can be formed between the perovskite type oxide layer 20 and the electrode layer 30. For this reason, ferroelectric capacitors and piezoelectric elements to which the perovskite type oxide layer 20 of the present embodiment is applied can be expected to have excellent characteristics and reliability.

In accordance with the present embodiment, even when the second oxide layer 26 is formed in multiple layers like the first embodiment, the perovskite type oxide layer 20 in a single layer having a desired crystal orientation can be obtained by the crystallization heat treatment.

Furthermore, in accordance with the present embodiment, like the first embodiment, by controlling the temperature to form the second oxide layer 26 and its layer structure, the crystal grain size of the perovskite type oxide layer 20 finally obtained can be optionally set. Since the crystal grain size influences the ferroelectric characteristic and piezoelectric characteristic, the ability to control the crystal grain size is extremely useful. For example, in the case of piezoelectric, its piezoelectric property can be controlled by changing the number of grain boundaries.

### 3. Third Embodiment

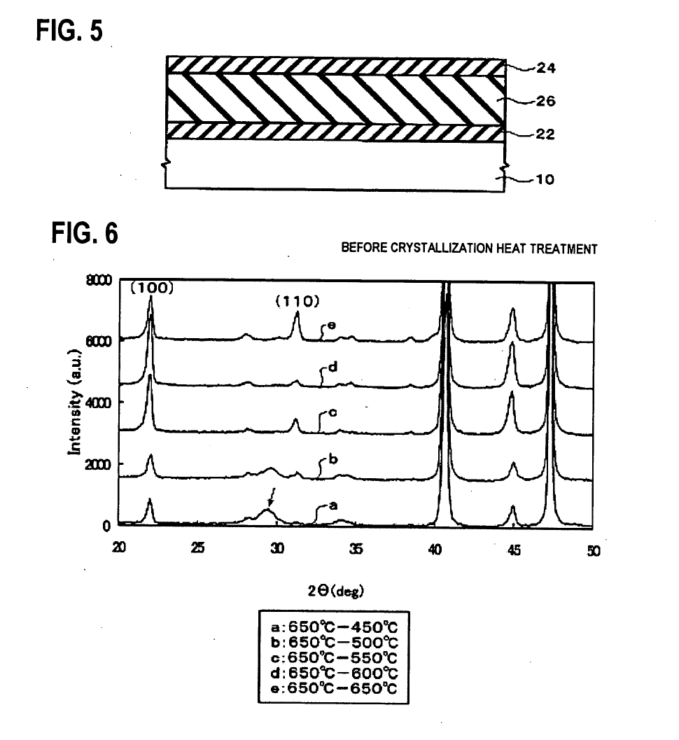

FIG. 5 is a cross-sectional view schematically showing a step of a manufacturing method in accordance with a third embodiment of the invention. It is noted that members shown in FIG. 5 that are substantially the same as those of the first embodiment shown in FIG. 1 and the second embodiment shown in FIG. 4 are appended with the same reference numbers, and their detailed description is omitted.

The present embodiment differs from the first embodiment or the second embodiment in that both of a perovskite type oxide layer and a pyrochlore layer are used as a second oxide layer.

(1) First, as shown in FIG. 5, a first oxide layer 22 is formed on a substrate 10. The first oxide layer 22 is formed to have a crystal orientation of a perovskite type oxide (also hereafter referred to as “first perovskite type oxide”) layer that is to be finally obtained. The substrate 10 is similar to the substrate in the first embodiment.

(2) Next, as shown in FIG. 5, a second oxide layer composed of second perovskite type oxide (hereafter referred to as a “second perovskite type oxide layer”) 26 is formed on the first oxide layer 22, like the second embodiment.

The second perovskite type oxide composing the second perovskite type oxide layer 26 has the same compositions as those of the first perovskite type oxide composing the first oxide layer 22, but a different structure from that of the first perovskite type oxide, for example, different crystal orientation and different crystal grain size.

The second perovskite type oxide layer 26 may preferably be crystallized at a temperature lower than the crystallization temperature of at least the first oxide layer 22, and at which organic compositions are sufficiently decomposed, although such temperature may differ depending on the kind of the second perovskite type oxide composing the second perovskite type oxide layer 26. The crystallization temperature of the second perovskite type oxide layer 26 is normally within such a temperature range. For example, when the first oxide layer 22 is composed of PZT, the second oxide layer (PZT) 26 can be formed at a temperature ranging from 500° C. to less than 650° C. Also, when the second oxide layer 26 is crystallized, organic compositions within the film are decomposed. Therefore, organic compositions (carbon residue) do not exist in the second oxide layer 26.

The second perovskite type oxide layer 26 may be formed by a method similar to the second embodiment.

(3) Then, as shown in FIG. 5, a second oxide layer composed of a pyrochlore layer (hereafter also referred to as a “pyrochlore layer”) 24 is formed on the second oxide 26 composed of the second perovskite type oxide.

The pyrochlore layer 24 has, like the first embodiment, pyrochlore crystal having the same elements as those of perovskite type oxide composing the first oxide layer 22. The pyrochlore layer 24 is formed at a temperature lower than the temperature at which the first oxide layer 22 composed of the first perovskite type oxide is formed. Also, the pyrochlore layer 24 is formed at a temperature higher than the temperature at which organic compositions within the film are decomposed. In other words, the forming temperature of the pyrochlore layer 24, although it differs depending on the kind of the pyrochlore type oxide, may preferably be a temperature lower than the crystallization temperature of at least the first oxide layer 22, and at which crystallization of the pyrochlore layer 24 takes place and organic compositions in the layer are sufficiently decomposed, like the first embodiment. Therefore, organic compositions (carbon residue) do not exist in the pyrochlore layer 24. Further, the pyrochlore layer 24 has an oxygen octahedral structure in its crystal structure, and therefore abundant oxygen for changing to perovskite type oxide.

The pyrochlore layer 24 may be formed by a method similar to the first embodiment.

(4) Then, an electrode layer 30 having a desired pattern is formed on the pyrochlore layer 24. This step may be conducted in a manner similar to the first embodiment.

(5) Next, as shown in FIG. 3, heat treatment (hereafter referred to as “crystallization heat treatment”) is conducted to crystallize the pyrochlore layer 24 and the second perovskite type oxide layer 26, thereby forming a perovskite type oxide layer 20.

The crystallization heat treatment is conducted at a temperature at which the pyrochlore layer 24 and the second perovskite type oxide layer 26 sufficiently undergo epitaxial growth on the first oxide layer 22, and preferably at a temperature lower than the crystallization temperature of the first oxide layer 22. The crystallization heat treatment in this step may be conducted at a temperature exceeding the crystallization temperature of the first oxide layer 22, but in this case, the temperature may be higher by up to a maximum of about 50° C.

If the temperature of the crystallization heat treatment is too low, the epitaxial growth of the pyrochlore layer 24 and the perovskite type oxide layer 26 becomes insufficient, and a desired crystal orientation cannot be obtained. On the other hand, if the temperature of the crystallization heat treatment is too high, an undesired deteriorated layer may be generated by diffusion of materials of the perovskite type oxide layer 20 and the electrode layer 30 between the two layers, and lattice vibration of the perovskite type oxide may become excessive such that oxygen vacancies would likely be generated in the perovskite type oxide.

For example, when the perovskite type oxide is PZT, the crystallization heat treatment may be conducted between 600° C. and 700° C. In this case, if the temperature of the crystallization heat treatment exceeds about 700° C., a deteriorated layer (for example, a layer containing lead and elements of the electrode layer) may be formed between the PZT layer and the electrode layer, and Pb vacancy caused by evaporation of lead from the surface of the PZT layer and oxygen vacancy due to Frenkel defects of titanium in the PZT layer would likely occur.

In this step, the pyrochlore layer 24 and the second perovskite type oxide layer 26 change to a layer of first perovskite type oxide. In other words, the pyrochlore layer 24 and the second perovskite type oxide layer 26 both become, by epitaxial growth, to have a structure having the same crystal orientation as that of the first perovskite type oxide composing the first oxide layer 22. As a result, as shown in FIG. 3, a perovskite type oxide layer 20 in a single layer which is originated from the first oxide layer 22, the second perovskite type oxide layer 26 and the pyrochlore layer 24 is formed. In this manner, the first oxide layer 22 functions as a buffer layer (i.e., a seed layer) having an orientation controlling function when the second perovskite type oxide layer 26 and the pyrochlore layer 24 change to first perovskite type oxide, such that the perovskite type oxide layer 20 can be formed at a relatively low temperature, and evaporation of lead can also be suppressed.

Also, in this step, the temperature of the crystallization heat treatment is lower than that of the conventional post annealing, its thermal energy is almost entirely consumed for changing the second perovskite type oxide and the pyrochlore to the first perovskite type oxide, and excessive thermal energy is not applied to the perovskite type oxide to be finally obtained, such that problems caused by high temperature heat treatment such as post annealing would be difficult to occur. Therefore, the perovskite type oxide layer 20 with an excellent crystal structure can be formed, and an excellent interface can be formed between the perovskite type oxide layer 20 and the electrode layer 30. As a result, high temperature heat treatment like the conventional post annealing is not additionally required.

In the embodiment described above, each of the pyrochlore layer 24 and the perovskite type oxide layer 26 is formed in a single layer. However, the present embodiment is not limited to such a structure, and at least one of the pyrochlore layer 24 and the second perovskite type oxide layer 26 may be composed of a plurality of laminated layers. In the present embodiment, even in this case, the perovskite type oxide layer 20 having the same crystal orientation as that of the first oxide layer 22 can be finally obtained by the crystallization heat treatment.

The present embodiment has the following characteristics.

In accordance with the present embodiment, a pyrochlore layer and a second perovskite type oxide layer are used as the second oxide layers 24 and 26, such that the perovskite type oxide layer 20 with few oxygen vacancies can be formed with relatively low energy.

In accordance with the present embodiment, because a pyrochlore layer and a second perovskite type oxide layer are used as the second oxide layers 24 and 26, organic compositions are sufficiently decomposed and removed when the oxide layers 24 and 26 are formed, and therefore carbon residue is not generated.

In accordance with the present embodiment, the perovskite type oxide layer 20 has an excellent crystal structure like the first embodiment, and an excellent interface can be formed between the perovskite type oxide layer 20 and the electrode layer 30. For this reason, ferroelectric capacitors and piezoelectric elements to which the perovskite type oxide layer 20 of the present embodiment is applied can be expected to have excellent characteristics and reliability.

In accordance with the present embodiment, even when the second oxide layer 26 is formed in multiple layers like the first embodiment, the perovskite type oxide layer 20 in a single layer having a desired crystal orientation can be obtained by the crystallization heat treatment.

Furthermore, in accordance with the present embodiment, like the first embodiment and the second embodiment, by controlling the temperature to form the second oxide layers 24 and 26 and their layer structure, the crystal grain size of the perovskite type oxide layer 20 to be finally obtained can be optionally set. Since the crystal grain size influences the ferroelectric characteristic and piezoelectric characteristic, the ability to control the crystal grain size is extremely useful. For example, in the case of piezoelectric, its piezoelectric property can be controlled by changing the number of grain boundaries.

### 4. Exemplary Embodiment

Exemplary embodiments of the invention are described below.

### 4.1. Exemplary Embodiment 1

First, a laminated body having a structure corresponding to the structure shown in FIG. 1 or FIG. 4 was formed and used as a sample. Each sample was formed from a substrate 10 composed of an iridium layer as a lower electrode, and a PZT layer as a first oxide layer 22. As second oxide layers 24 and 26, pyrochlore or PZT layers having the same compositions as those of the first oxide layer 22 were used. Five kinds of samples were formed by changing the forming temperature of the second oxide layer. These samples are referred to as samples a through e. X-ray diffraction diagrams of these samples a through e are shown in FIG. 6.

Concretely, the samples were formed in the following manner. A PZT layer corresponding to the first oxide layer having the compositions described above was formed on the iridium electrode by a sol-gel method. The PZT layer was crystallized at 650° C. Then, a coating film was formed on the PZT layer by using a sol-gel material, the film was dried and cleaned, and the coated film was heat treated at one of several different temperature levels, whereby a pyrochlore layer or a perovskite type oxide layer corresponding to the second oxide layer was formed. The temperature for forming the second oxide layer was, as shown in FIG. 6, 450° C. for the sample a, 500° C. for the sample b, 550° C. for the sample c, 600° C. for the sample d, and 650° C. for the sample e.

It is observed from FIG. 6 that the samples a and b each had a peak of pyrochlore at a section indicated by an arrow mark (at about 29 deg). Therefore it was confirmed that the second oxide layer in each of the samples a and b was a pyrochlore layer. Also, no peak was observed in the samples c, d and e, and therefore it was confirmed that their second oxide layer was perovskite type oxide with a (100) orientation.

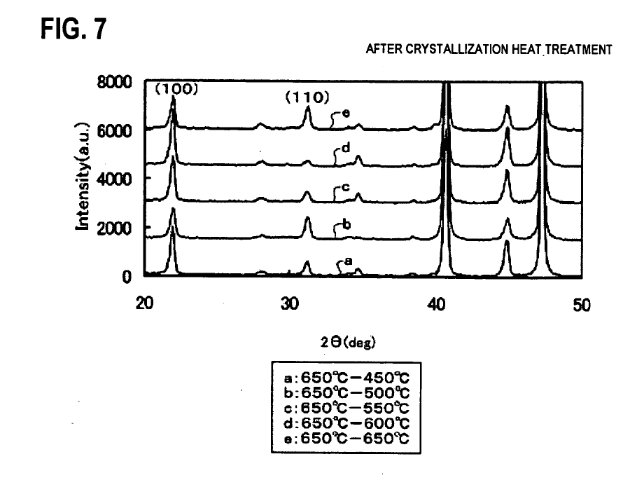

Then, each of the samples a through e was heat treated (subjected to crystallization heat treatment) for 5 minutes at 650° C., whereby the pyrochlore layer or perovskite type oxide layer which is the second oxide layer was crystallized by epitaxial growth. X-ray diffraction diagrams of the resultant samples a through e are shown in FIG. 7. It is observed from FIG. 7 that each of the samples subjected to crystallization heat treatment did not have a peak indicative of pyrochlore, but had a noticeable peak in a (100) orientation. Therefore, in accordance with the exemplary embodiments, it was confirmed that, by applying crystallization heat treatment to the second oxide layer at the same temperature as the crystallization temperature of the first oxide layer (PZT layer), PZT having an excellent orientation could be obtained.

### 4.2. Exemplary Embodiment 2

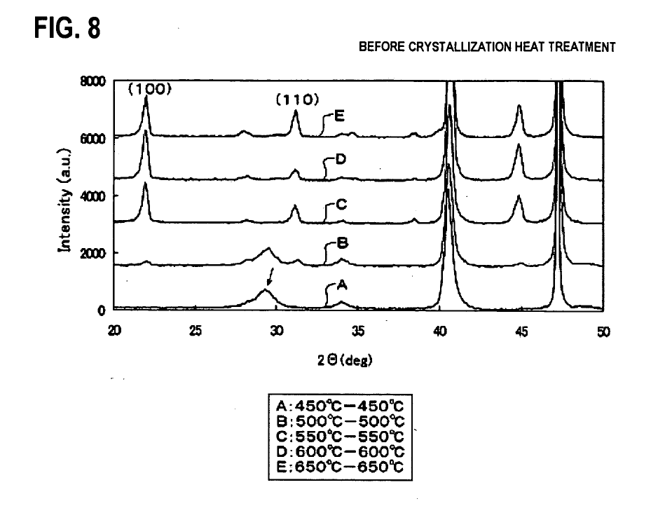

Five kinds of samples (samples A through E) were obtained in a manner similar to the exemplary embodiment 1, except that temperature conditions for crystallizing the first oxide layer and the second oxide layer were set as indicated in FIG. 8. In the five kinds of samples, a layer corresponding to the first oxide layer and a layer corresponding to the second oxide layer were heat treated at the same temperature, respectively. In other words, the first and second oxide layers were heat treated at 450° C. for the sample A, at 500° C. for the sample B, at 550° C. for the sample C, at 600° C. for the sample D, and at 650° C. for the sample E, respectively.

FIG. 8 shows X-ray diffraction diagrams of the samples A through E before the final crystallization heat treatment. It is observed from FIG. 8 that the samples A and B each had a peak of pyrochlore. Also, it is observed that the samples C, D and E did not have a peak of pyrochlore, but each had a noticeable peak in a (100) orientation.

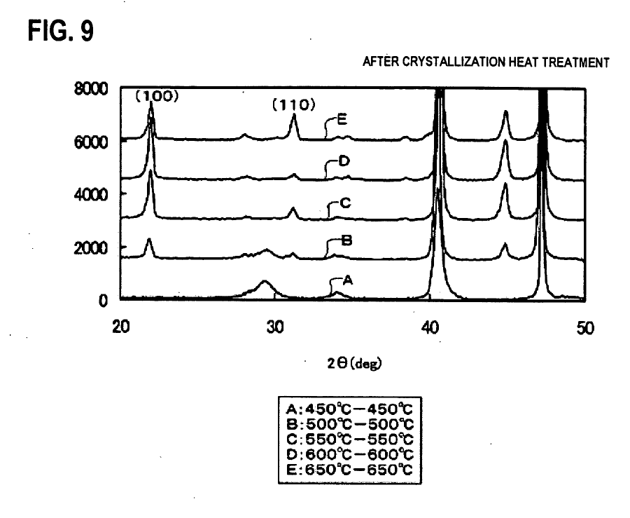

Further, each of the samples was subjected to crystallization heat treatment for 5 minutes at 650° C. X-ray diffraction diagrams of the resultant samples obtained are shown in FIG. 9. It is confirmed from FIG. 9 that the samples A and B each still had a peak of pyrochlore.

It was confirmed from the above that, when the first oxide layer was a pyrochlore layer, pyrochlore existed even after the final crystallization heat treatment was conducted. On the other hand, in the case of the samples C, D and E in which the first oxide layer was crystallized at 550° C. or higher, the oxide layer was a perovskite type oxide layer, and the layer finally obtained was also a perovskite type oxide layer.

What is claimed is:

1. A method for manufacturing a perovskite type oxide layer, comprising the steps of:
forming, above a substrate, a first oxide layer composed of perovskite type oxide;
forming, above the first oxide layer, a second oxide layer composed of at least one of a perovskite type oxide layer crystallized at a temperature lower than a crystallization temperature of the first oxide layer and a pyrochlore layer having elements identical with elements of the perovskite type oxide;
forming an electrode layer above the second oxide layer; and
conducting a heat treatment.

2. A method for manufacturing a perovskite type oxide layer according to claim 1, wherein the heat treatment is conducted at a temperature below the crystallization temperature of the first oxide layer.

3. A method for manufacturing a perovskite type oxide layer according to claim 1, wherein the second oxide layer includes the pyrochlore layer, and the pyrochlore layer is changed to a perovskite type oxide layer by the heat treatment.

4. A method for manufacturing a perovskite type oxide layer according to claim 1, wherein, in the step of forming the first oxide layer, the first oxide layer is formed with a specific crystal orientation.

5. A method for manufacturing a perovskite type oxide layer according to claim 1, wherein the first oxide layer is formed by a liquid phase method, and the second oxide layer is formed by a vapor phase method.

6. A method for manufacturing a ferroelectric memory, comprising the steps of:
forming, above a substrate, a lower electrode;
forming, above the lower electrode, a first oxide layer composed of perovskite type oxide;
forming, above the first oxide layer, a second oxide layer composed of at least one of a perovskite type oxide layer crystallized at a temperature lower than a crystallization temperature of the first oxide layer and a pyrochlore layer having elements identical with those of the perovskite type oxide;
forming an upper electrode above the second oxide layer; and
conducting a heat treatment.

7. A method for manufacturing a surface acoustic wave element, comprising the steps of:
forming, above a substrate, a first oxide layer composed of perovskite type oxide;
forming, above the first oxide layer, a second oxide layer composed of at least one of a perovskite type oxide layer crystallized at a temperature lower than a crystallization temperature of the first oxide layer and a pyrochlore layer having elements identical with elements of the perovskite type oxide;
forming an electrode above the second oxide layer; and
conducting a heat treatment.
